(19) United States
(12) Patent Application Publication
(10) Pub. No.: US 2005/0273283 A1
(43) Pub. Date: Dec. 8, 2005

(54) Superresolution off axis telescope using the maximum in the laplacian orthogonal to isophote ridge tops

(76) Inventor: David Joel Maker, Huntsville, AL (US)

Correspondence Address: David Maker, 7807 Hilton Dr., Huntsville, AL, 35802, US

(21) Appl. No.: 10/861,141

(22) Filed: Jun. 7, 2004

(51) Int. Cl. G01R 13/00; G06F 19/00

(52) U.S. Cl. 702/66

(57) ABSTRACT

There are many de-convolution algorithms (using Fourier transforms for example) that allow calculation of kᵢ and Rᵢ given the image values of I (xᵢ, yᵢ). The problem arises when the PSF's are closer together than a Rayleigh length: the number of artifact images (false images) available from a typical de-convolution algorithm may then be very large. Thus the overall probability of a false de-convolved image also is very large. This is the ambiguous image problem first identified by Toraldo di Francia (Reference 1). We solve this problem by finding the maximum in the Laplacian (i.e., take largest second derivative) along the isophote ridges on which the first derivative=0 (on a circle around the maximum). To correctly use this algorithm we must apply it to an off axis telescope.

### CROSS-REFERENCE TO RELATED APPLICATIONS

Not Applicable

### BACKGROUND OF THE INVENTION

The CLEAN algorithm takes the values of the intensity from the highest intensity regions of one image and then adds them to a second image (Reference 8—Crilly ,1991). This algorithm picks up regions close the maxima and some regions along “ridge lines”. But it also picks up regions between the ridge lines near the peak. These regions then contribute de-convolution artifacts to the imaging system containing ambiguous images in the way discussed above. In contrast, the method used here only includes regions along the ridgelines with maximum second derivatives thus excluding those extraneous regions. This is in principle a far better super-resolution method than the CLEAN algorithm. However, this method and CLEAN both make use of numerical relaxation at the end. Thus the CLEAN algorithm is the next best competitor to this method but is still not good enough since it requires that the number of points be known beforehand for many configurations of interest. Other alternatives such as Reference 9 (Pask,1993) and Lucy Richardson (Reference 8—Crilly, 1991), that use modified Fourier transforms, alteration of the frequency space and then back (modified) Fourier transforms over the whole X, Y plane (Reference 4—Sementelli, 1955), give many image artifacts because of the their use of the whole X,Y plane in the de-convolution process.

The mathematical problem of super-resolution is to extract PSF centers Xᵢ, Yᵢ and amplitudes kᵢ from one single (non-coherent) intensity function when the centers of these PSFs are within the Rayleigh length. Thus the functions kᵢ(J₁(Rᵢ)/Rᵢ)² must be disentangled from the sum I(x, y)=Σkᵢ(J₁(Rᵢ)/Rᵢ)² even if some noise is present. Therefore we have to devise ways to solve for Xᵢ, Yᵢ and kᵢ. These kᵢ's can be in principle solved for given I(x, y)'s. There are many de-convolution algorithms (using Fourier transforms for example) that allow calculation of kᵢ and Rᵢ given the image values of I(xᵢ, yᵢ). The problem arises when the psf's are closer than a Rayleigh length: the number of artifact images (false images) available for a de-convolution algorithm is then very large. Thus the probability of obtaining a false de-convolved image, called an image artifact, grows exponentially large. This is the ambiguous image problem first identified by Toraldo di Francia (Reference 1-1955).

### BRIEF SUMMARY OF THE INVENTION

We conjecture here that the above derivative results for a single PSF near R=0 survive as orthogonal partial derivatives even when several PSF's are very close together. Therefore, we find local regions with zero first derivatives (on a circle around a given maximum) and then look for regions of maximum second derivatives in orthogonal directions to the lines of these zero first derivatives (later use numerical relaxation de-convolution on just these regions).

Thus the procedure is to:
1 ) One smoothing of the data from a 2 dimensional CCD output. Thus set the electron count in each pixel equal to the average in the surrounding pixels.

Keep the original image in a second file.
2)Program used to locate regions of maximum second derivatives in the CCD output of the smoothed image in a local region moving radially away from a point of maximum intensity. Thus program takes two sets of derivatives at adjoining pixels then takes the difference in those two values. The program does this over the entire smoothed image. It records the X,Y positions of these points of maximum second derivatives (i.e., maximum Laplacians).
3) The program is used to take differences to take derivatives in circles around local maxima. The X,Y points at which these first derivatives are maxima are recorded. Note this procedure is done along orthogonal lines to those of the maximum laplacian procedure.
4) The points of intersection of the regions of maximum laplacian and zero orthogonal first derivatives are recorded.
5) The numerical relaxation deconvolution procedure (shown below to be equivalent to least squares deconvolution) is then used only on the X,Y points on the original image to create a deconvolved superresolved image.
6) Apply this procedure to images created in a off axis reflecting telescope, thus the image is reflected from the primary to a secondary located outside the optical path.

After the fortran simulations were written this procedure was in fact used in a 400 foot hallway (using a PC) to deconvolve the image. It obtained superresolved images. Thus this superresolution telescope has been built and tested with this associated software procedure outlined in steps 1 through 5.

In this regard there are many de-convolution algorithms (using Fourier transforms for example) that allow calculation of kᵢ and Rᵢ given the image values of I(xᵢ, yᵢ). The problem arises when the PSF's are closer together than a Rayleigh length: the number of artifact images (false images) available from a typical de-convolution algorithm may then be very large. Thus the overall probability of a false de-convolved image also is very large. This is the ambiguous image problem first identified by Toraldo di Francia (Reference 1). We solve this problem by finding the maximum in the Laplacian (i.e., take largest second derivative) along the isophote ridges on which the first derivative=0 (on a circle around the maximum).

To solve the ambiguous image problem, first identified by Toraldo di Francia (1955), we identify three regions and associate with each of these regions a probability density of the de-convolution thus resulting in an artifact (or false) image

### DETAILED DESCRIPTION OF INVENTION

The mathematical problem of extracting PSF centers Xᵢ, Yᵢ and amplitudes kᵢ from one single (non-coherent) intensity function (Reference 11—Tychinsky, 1991) for a circular aperture is summarized below. The individual functions kᵢ (J₁(Rᵢ)/Rᵢ)² must be disentangled from their sum,

$$I ( x , y ) = {\sum }_{M = 1}^{N} {{k}_{i} ( \frac{{J}_{1} ( {R}_{i} )}{{R}_{i}} )}^{2} , with$$

$${R}_{i} = \sqrt{{( {X}_{i} - x )}^{2} + {( {Y}_{i} - y )}^{2} + {( {Z}_{i} - z )}^{2}}$$

even with some noise. The object then is to solve for Xᵢ, Yᵢ and kᵢ. Specifically we are concerned here with PSF's that are closer than the Rayleigh limit, the problem of super-resolution.

In that regard we begin by writing down derivatives of an individual PSF in I(x, y) given by,

$$\begin{matrix}{I}_{i} ( x , y ) = {{k}_{i} ( \frac{{J}_{1} ( {R}_{i} )}{{R}_{i}} )}^{2} \\ = {{k}_{i} ( {J}_{1}^{′} ( {R}_{i} ) + {J}_{2} ( {R}_{i} ) )}^{2} \\ = {( \frac{1}{2} {k}_{i} ( {J}_{o} ( {R}_{i} ) - {J}_{2} ( {R}_{i} ) ) + {J}_{2} ( {R}_{i} ) )}^{2} \\ = {{k}_{i} ( \frac{1}{2} ( {J}_{o} ( {R}_{i} ) + {J}_{2} ( {R}_{i} ) ) )}^{2}\end{matrix}$$

$$\begin{matrix}So , ⅆ {I}_{i} ( x , y ) / ⅆ R = {k}_{i} ( \frac{2}{2} ( {J}_{o}^{′} ( {R}_{i} ) + {J}_{2}^{′} ( {R}_{i} ) ) ( {J}_{o} ( {R}_{i} ) + {J}_{2} ( {R}_{i} ) ) ) \\ = {k}_{i} ( \frac{2}{2} ( - {J}_{1} ( {R}_{i} ) + \frac{1}{2} ( {J}_{1} ( {R}_{i} ) - {J}_{3} ( {R}_{i} ) ) ) \\ ( {J}_{o} ( {R}_{i} ) + {J}_{2} ( {R}_{i} ) ) ) \\ = {k}_{i} ( - \frac{1}{2} ( {J}_{1} ( {R}_{i} ) + {J}_{3} ( {R}_{i} ) ) ( {J}_{o} ( {R}_{i} ) + {J}_{2} ( {R}_{i} ) ) ) \\ = first derivative\end{matrix}$$

$$But since {J}_{1} ( {R}_{i} ) \& {J}_{3} ( {R}_{i} ) = 0 at R = 0 we have at R = 0 that$$

$${I}^{′} ( x , y ) = 0. \\ The second derivative is found from \text{:}$$

$$\begin{matrix}{I}^{′′} ( x , y ) = {k}_{i} ( - \frac{1}{2} ( {J}_{1}^{′} ( {R}_{i} ) + {J}_{3}^{′} ( {R}_{i} ) ) ( {J}_{o} ( {R}_{i} ) + {J}_{2} ( {R}_{i} ) ) + \\ ( {J}_{1} ( {R}_{i} ) + {J}_{3} ( {R}_{i} ) ) ( {J}_{o}^{′} ( {R}_{i} ) + {J}_{2}^{′} ( {R}_{i} ) ) ) \\ = ( not writing the R dependence here so the our \\ expressions can be written more succinctly ) \\ {k}_{i} ( - \frac{1}{2} ( ( {J}_{0} - {J}_{2} ) + ( {J}_{2} - {J}_{4} ) ) ( {J}_{0} + {J}_{2} ) + \\ ( {J}_{1} + {J}_{3} ) ( - {J}_{1} + \frac{1}{2} ( {J}_{1} - {J}_{3} ) ) ) \\ = {k}_{i} ( - \frac{1}{2} ( ( {J}_{0} - {J}_{4} ) ) ( {J}_{0} + {J}_{2} ) - \frac{1}{2} {( {J}_{1} + {J}_{3} )}^{2} ) \\ = At R = 0 , {J}_{4} = 0 , {J}_{2} = 0 , {J}_{1} = 0 {J}_{3} = 0 , \\ thus , the second derivative \\ = - \frac{1}{2} {k}_{i} {J}_{0}^{2}\end{matrix}$$

Therefore, the modulus of the second derivative is maximum at R=0 since J₀ is maximum there. Again at R=0, the first derivative=0 and |second derivative|=maximum. Recall that one can characterize a function by its derivatives (as in a Taylor expansion).

Basic Assumption Made in Our Super-resolution Algorithm

We conjecture here that the above derivative results for a single PSF near R=0 survive as orthogonal partial derivatives even when several PSF's are very close together. Therefore, we find local regions with zero first derivatives (on a circle around a given maximum) and then look for regions of maximum second derivatives in orthogonal directions to the lines of these zero first derivatives (later use numerical relaxation de-convolution on just these regions).

To solve the ambiguous image problem, first identified by Toraldo di Francia (1955), we identify three regions and associate with each of these regions a probability density of the de-convolution thus resulting in an artifact (or false) image.

Let P₁(x₁, y₁) be the probability density inside regions (or sets of points) of small tangential derivatives at {x₁, y₁}. Thus we take our tangential derivative (φ =azimuthal angle):
dl(x,y)/dφ=0,
which is the first derivative taken tangentially to a circle around the point of highest intensity in a given imaged blob (in practice we find the minimums of this derivative on the circle). This gives us the set {x₁, y₁} which become “ridges” on the isophote presentation of the image. We parameterize these ridge line {x₁, y₁i} regions with a distance parameter, we call “s”. But also along “s”, we have regions {x₂, y₂} of largest Laplace filter return, i.e., have largest modulus of the second derivatives. The probability density of artifacts here is P₂(x₂, y₂). So let:
|∇²|(x, y)|=|∂²|(x, y)/∂s²|
be the modulus of the partial second derivative along those {x₁,y₁} ridge lines and so it is orthogonal to the direction where the first derivative is taken (implied by our conjecture). Let the actual region where the PSF's centers are located be {x_{A}, y_{A}}. The probability density of artifacts (i.e., P_{A}(X_{A}, Y_{A})) here of course is zero. The probability density of artifact images outside these three regions, P₀(x₀, y₀) is very high inside the Rayleigh region. The total probability for de-convolved false artifact solutions is then:
∫P₀(x, y)dA=∫P₀(x₀, y₀)dA+∫P₁(x₁, y₁)dA+∫P₂(x₂, y₂)dA.
(counting overlap regions only once and taking maximum P in the overlap region) where
∫P₀(x₀, y₀)dA is the outside artifact contribution
∫P₁(x₁, y₁)dA is the “ridges” contribution
∫P₂(x₂, y₂)dA is the maximum second derivative region contribution

But according to our above conjecture (concerning the PSF derivatives) the regions of highest Laplace filter return and smallest tangential first derivative (each being orthogonal to the other) intersect at the PSF points i.e., [{x₁, y₁}∩{x₂, y₂}]={x_{A}, y_{A}). Note this excludes the second derivative high points on the circular diffraction pattern outside the central blobby Airy PSF region which would be a problem if only a Laplace filter is used. But the probability for an artifact:
∫P(x, y)dA>>∫P_{A}(x_{A}, y_{A})dA) and P_{A}(x_{A}, y_{A})=0
So, we significantly decrease the probability of obtaining such artifacts by restricting our de-convolution to the {x₁, y₁}∩{x₂, y₂} region (i.e., the intersection of the {x₁,y₁} and {x₂,y₂} regions). In this way we solve the ambiguous image problem of Toraldo di Francia.

We then use numerical relaxation de-convolution (which we prove below to be equivalent to a least squares de-convolution) on the region intersecting the Laplace filter maxima and the small tangential derivatives to solve for the respective kᵢ's and further delineate the boundaries of the {x_{A}, y_{A}} region since they appear fuzzy due to noise. The noise problem is also addressed by “smoothing” once. Since at least an estimate is made here as to where on the image plane the psf centers are (the imaged objects) this part of the,algorithm detects the CSO condition and makes its inferences without actual de-convolution.
Numerical Relaxation and Least Squares

$$Let \overline{I} ( {X}_{i} , {Y}_{i} ) = {\sum }_{j = 1}^{N} {{k}_{j} ( \frac{{J}_{1} ( {R}_{ij} )}{{R}_{ij}} )}^{2} ,$$

where \overline{I}(Xᵢ,Yᵢ) is the measured data intensity at the point (Xᵢ,Yᵢ), I(xᵢ, yᵢ) is the intensity that we will obtain from the our de-convolution (i.e., 3) result, and N is the number of objects (that may be 2, 3, or 4 for now) in the image.

The square of the error η, is written as:

$${\sum }_{α = 1}^{N} {( I ( {X}_{α} , {Y}_{α} ) - \overline{I} ( {X}_{α} , {Y}_{α} ) )}^{2} = {η}^{2} \qquad ( 1 )$$

and the least squares algorithm (Reference 7—Andrews, 1988) starts with determining the extrema of η² with respect to the test choices of PX and PY in Equation (1). \overline{I} is not minimized with respect to PX and PY since it is pure data and “I(x, y)” is an unknown function of PX and PY. To find I(x, y), it is necessary to take derivatives with respect to PX and PY:

$$\begin{matrix}\frac{\partial }{\partial ( PX )} ( {\sum }_{α = 1}^{N} {( I ( {X}_{α} , {Y}_{α} ) - \overline{I} ( {X}_{α} , {Y}_{α} ) )}^{2} ) = 0 \\ or , {\sum }_{α = 1}^{N} 2 ( \frac{\partial }{\partial ( PX )} I ( {X}_{α} , {Y}_{α} ) ) ( I ( {X}_{α} , {Y}_{α} ) - \overline{I} ( {X}_{α} , {Y}_{α} ) ) = 0 \\ and \frac{\partial }{\partial ( PY )} ( {\sum }_{α = 1}^{N} {( I ( {X}_{α} , {Y}_{α} ) - \overline{I} ( {X}_{α} , {Y}_{α} ) )}^{2} ) = 0 & ( 2 ) \\ or , {\sum }_{α = 1}^{N} 2 ( \frac{\partial }{\partial ( PY )} I ( {X}_{α} , {Y}_{α} ) ) ( I ( {X}_{α} , {Y}_{α} ) - \overline{I} ( {X}_{α} , {Y}_{α} ) ) = 0 \\ with one solution being \text{:} & ( 3 ) \\ \frac{\partial }{\partial ( PX )} I ( {X}_{α} , {Y}_{α} ) = 0 , and other \frac{\partial }{\partial ( PY )} I ( {X}_{α} , {Y}_{α} ) = 0 & ( 4 )\end{matrix}$$

Since \overline{I}(X_{α},Y_{α}) is just our data then I(X_{α},Y_{α}) is the function minimized with respect to PX, PY. If the X_{α}, Y_{α} is the same as the associated PX, PY then in a random test on the fuzzy region close to the {x₁, y₁}∩{x₂, y₂} region (this is used in the computer code because of noise) we have that:

$${( \frac{{J}_{1} ( {R}_{ij} )}{{R}_{ij}} )}^{2} = 1 ,$$

so that we have a square matrix of a repeated list of kᵢ's.

$$Thus , I ( {x}_{i} , {y}_{i} ) = {\sum }_{j = 1}^{N} {{k}_{j} ( \frac{{J}_{1} ( {R}_{ij} )}{{R}_{ij}} )}^{2} = {\sum }_{j = 1}^{N} {k}_{j} \cdot 1 = F \qquad ( 5 )$$

When this is put back into Equation 4, we see that it is minimized (relaxed) with respect to the test PX, PY points, and we not only have the correct (PX, PY) positions but also the correct kᵢs for the point sources. In this way, the locations of the correct PSF source locations and intensities are found using ‘numerical relaxation’. This is a standard de-convolution technique that did not require a-priori knowledge of the number of objects.

Standard de-convolution algorithms unfortunately would have included ∫P₀(x₀, y₀)dA for example and therefore have a much higher artifact return. In that regard, the CLEAN algorithm (which also uses numerical relaxation) manages to catch only part of this {X_{A}, Y_{A}} region since it only goes a short distance down the ridges and it catches more and more non-ridge areas as more points are transferred over (thus adding in some ∫P₀(x₀, y₀)dA ), therefore increasing the probability of obtaining image artifacts from the de-convolution. We have explicitly tried to capture all of this {X_{A}, Y_{A}} region with this method, using our conjecture (on the PSF derivatives) as a guide.

Another way of looking at this theory is that the restricted region for the de-convolution consists of lines here, not the entire X, Y plane as in standard de-convolution techniques. Thus we have reduced the dimensionality used in the de-convolution from two dimensions (of the X, Y plane) to these one dimensional lines. We have therefore done “de-convolution by dimensional reduction”. In practice the image is smoothed just once for finding the zero in the derivative of the intensity along a line and the maxima in the second derivative. Given the resulting coordinates of these lines (found from the smoothed image), the numerical relaxation de-convolution is actually done on the original unsmoothed image.

Other more miscellaneous research might involve the interesting analogy between the Rayleigh criterion (as a resolution limit) and the uncertainty principle (Reference 10—Vigoureux, 1991). If these kinds of methods can be used to overcome the Rayleigh limit (and they have experimentally been proven to accomplish this) they might also be used to overcome the uncertainty principle of quantum mechanics, with the implication that underneath the theoretical facade of quantum mechanics is a classical mechanical underpinning after all. This would be an important consequence of this work not directly tied to target recognition.
1) G. Toraldo di Francia, Super Gain Antennas and Optical Resolving Power, Nuovo Ciento, 9(3), 1952, p 426
2) E. Abbe, Beitrage zur Theorie des Mikroskops un der Mikroskopischen Wahrnehmung, Arch.Mikrosk., Anal. 9(27), 1873, p 413
3) Lord Rayleigh, On the Theory of Optical Images, with Special Reference to the Microscope, The London, Edinburgh and Dublin Philosophical Magazine and Journal, 42, 1896, p 167
4) P.Sementelli, Analysis of the Limit of Super-resolution, J. Opt. Soc. of Am.,45(7),1955, p 497
5) G. Toraldo Di Francia, Resolving Power and Information, J.Optc. Soc.of Am.,45(7),1955, p 497
6) J. Lim, Advanced Topics In Signal Processing, Prentice Hall, 1988,p 128
7) H. Andrews, Digital Image Reconstruction, Prentice Hall, 1988,p 190
8) B. Crilly, A Quantitative Evaluation of Various Iterative De-convolution Algorithms, IEEE Transactions on Instrumentation and Measurement, 40 (3), 1991,p 558
9) C. Pask, Simple Optical Theory of Super-resolution.J.Opt.Soc.AmA.,10(1 1), 1993, p 2267
10) J. Vigoureux, Detection of Nonradiative Fields in Light of the Heisenberg Uncertainty Principle and the Rayleigh Criterion, Applied Optics, 31(16),1992,p.3170
11)V.Tychinsky, On Super-resolution of Phase Objects, Optics Communication, 74(41), 1991,p 7
12)E. Volochkov, A Method of Two-Dimensional Angular Super-resolution of Coherent Radiation Sources Based on Estimating of One-dimensional Dumped Harmonic Signal Parameters, Radioteknika I Electronika, 38(7), 1993, p 1291
13)X. Lianggui, Sensitivity Analysis of Super-resolution Algorithm Based on Gram-Schmidt Orthogonality Method, Ten Tzu Hsueh Poa/Acta Electronica Sinica, 21(3) 19993,p 80
14) D Slepian, Prolate Spheroidal Wave Functions, Fourier Analysis and Uncertainty-I, Bell Systems Technical Journal, 43(1), 1961, p 4

1. We claim that to do the very best superresolution we must find the regions of maximum of the Laplacian that intersect with lines of orthogonal zero first derivatives. Then do the deconvolution on these regions.

2. We claim that this superresolution method can be combined with an off axis reflecting telescope to give a true superresolution telescope.
